(19) United States
(12) Patent Application Publication
(10) Pub. No.: US 2013/0076203 A1
(43) Pub. Date: Mar. 28, 2013

(54) CERAMIC BODY AND METHOD FOR PRODUCING THE SAME

(71) Applicant: Murata Manufacturing Co., Ltd., Nagaokakyo-shi (JP)

(72) Inventors: Junichi SAITO, Nagaokakyo-shi (JP); Yoshinori UEDA, Nagaokakyo-shi (JP); Tatsuo KUNISHI, Nagaokakyo-shi (JP)

(73) Assignee: MURATA MANUFACTURING CO., LTD., Nagaokakyo-shi (JP)

(21) Appl. No.: 13/678,683

(22) Filed: Nov. 16, 2012

Related U.S. Application Data
(63) Continuation of application No. PCT/JP2011/060511, filed on May 2, 2011.

(30) Foreign Application Priority Data
May 21, 2010 (JP) 2010-117499

(51) Int. Cl. H01G 4/12; H01C 7/00; H05K 1/03; H01F 17/00; H01L 41/083

(52) U.S. Cl. CPC H01G 4/12; H01F 17/0013; H01L 41/083; H05K 1/0306; H01C 7/008
USPC 310/311; 427/105; 361/321.2; 336/200; 174/258; 338/22 R

(57) ABSTRACT

A ceramic body including therein conductors more effectively prevents ingress of moisture into voids between the conductors and the ceramic body. A supercritical fluid containing a monomer flows in the voids between internal electrode layers and a ceramic laminated body. Then, the voids between the internal electrode layers and the ceramic laminated body are filled with a polymer by the polymerization of the monomer.

### BACKGROUND OF THE INVENTION

1. Field of the Invention

The present invention generally relates to a ceramic body and a method for producing the ceramic body, and more particularly, relates to, for example, a chip-type ceramic electronic component such as a laminated ceramic capacitor, and a method for producing the ceramic electronic component.

2. Description of the Related Art

Conventionally, a laminated ceramic capacitor as an example of a ceramic body is produced in the following way.

First, slurry is prepared which contains a ceramic raw material powder. This slurry is formed into a sheet to prepare ceramic green sheets. Onto the surfaces of the ceramic green sheets, a conductive paste as a raw material for internal electrode layers is applied in accordance with a predetermined pattern. This conductive paste is composed of a metal powder, a solvent, and varnish.

Next, the multiple ceramic green sheets with the conductive paste applied are stacked, and subjected to thermocompression bonding to prepare an integrated raw laminated body. This raw laminated body is subjected to firing to prepare a ceramic laminated body. This ceramic laminated body has a plurality of internal electrode layers formed therein. The internal electrode layers have some end surfaces exposed at the external surface of the ceramic laminated body.

Next, a conductive paste as a raw material for external electrode layers is applied onto the outer surface of the ceramic laminated body at which some end surfaces of the internal electrode layers are exposed, and then subjected to firing. This conductive paste is composed of a metal powder, glass frit, a solvent, and varnish. Thus, external electrode layers are formed on the outer surface of the ceramic laminated body so as to be electrically connected to the specific internal electrode layers.

Finally, in order to enhance soldering performance, plating layers are formed on the surfaces of the external electrode layers, if necessary.

In the above production process, for example, in the case of forming plating layers on the surfaces of the external electrode layers, the ingress of moisture is caused due to fine voids present in the external electrode layers. In addition, when the laminated ceramic capacitor as an example of the ceramic body is used in a high-humidity environment, the ingress of moisture is caused due to fine voids present in the external electrode layers. As for the ingress of moisture from the external electrode layers, there is a problem that the moisture reaches fine voids at the interfaces between the internal electrode layers and ceramic layers present in the ceramic laminated body, thereby causing a decrease in insulation resistance.

Therefore, for example, Japanese Patent Application Laid-Open No. 2001-102247 proposes the configuration of a chip-type electronic component for solving the problem mentioned above. The chip-type electronic component proposed in Japanese Patent Application Laid-Open No. 2001-102247 is a chip-type electronic component obtained by forming, on both ends of a rectangular ceramic substrate, an external terminal electrode composed of a thick film conductor underlayer and a surface plating layer, where the external terminal electrode is impregnated with a water-shedding member. This impregnation suppresses the ingress of moisture into porous portions of the external terminal electrodes, even when the chip-type electronic component is left out in high-humidity places. As a result, moisture is prevented from reaching the electronic component body through the surface plating layer and the thick film conductor interlayer.

In addition, for example, Japanese Patent Application Laid-Open No. 2-301113 proposes the configuration of a laminated ceramic electronic component, and a method for producing the component, for solving the problem mentioned above. In the laminated ceramic electronic component proposed in Japanese Patent Application Laid-Open No. 2-301113, defects such as gaps, pores, and pinholes in a ceramic laminated body or in external electrodes are filled with an inorganic oxide. In addition, in a method for producing a laminated ceramic electronic component as proposed in Japanese Patent Application Laid-Open No. 2-301113, after the formation of the ceramic laminated body, or of the external electrodes on the ceramic laminated body, the ceramic laminated body is immersed in a solution of an organic metal such as a metal alkoxide to impregnate, with the organic metal, defects such as gaps, pores, and pinholes in the ceramic laminated body or in the external electrodes, and then heated to decompose the organic metal into an inorganic oxide. This method suppresses the ingress of moisture into the gaps or pores mentioned above.

In the configuration of the chip-type electronic component described in Japanese Patent Application Laid-Open No. 2001-102247, the water-shedding substance remains in the external terminal electrodes. For this reason, in the case of forming plating layers in a subsequent step, defective plating deposition is likely to be caused on the surfaces of the external terminal electrodes, and in the case of mounting the chip-type electronic component by soldering onto a substrate or the like, defects may be caused in some cases.

In addition, in the configuration of the chip-type electronic component described in Japanese Patent Application Laid-Open No. 2001-102247, the excessively small amount of water-shedding substance remaining in the external terminal electrodes fails to achieve the effect of suppressing the ingress of moisture into the electronic component body, whereas the excessively large amount of water-shedding substance remaining in the external terminal electrodes causes defective plating deposition. For this reason, it is difficult to control the treatment condition for the impregnation of the external terminal electrode with the water-shedding substance.

On the other hand, in Japanese Patent Application Laid-Open No. 2-301113, the ceramic laminated body is immersed in the solution of an organic metal such as a metal alkoxide to implant the inorganic oxide into defects such as gaps in the ceramic laminated body or in the external electrodes. However, this method fails to fill nano-level fine voids with the inorganic oxide, and thus has an insufficient effect for suppressing the ingress of moisture into the voids.

### SUMMARY OF THE INVENTION

Therefore, preferred embodiments of the present invention provide a ceramic body including therein conductors and which is capable of more effectively preventing ingress of moisture into voids between the conductors and the ceramic body, and a method for producing the ceramic body.

A ceramic body in accordance with a preferred embodiment of the present invention is a ceramic body including therein a conductor, and a polymer arranged to fill a void between the conductor and the ceramic body.

This configuration makes it possible to more effectively prevent the ingress of moisture into the void between the conductor and the ceramic body in the ceramic body including therein the conductor.

A method for producing a ceramic body to fill a void between a conductor and a ceramic body in accordance with another preferred embodiment of the present invention includes the steps of allowing a supercritical fluid containing a monomer to enter into a void between the conductor and the ceramic body, and filling the void between the conductor and the ceramic body with a polymer by polymerization of the monomer.

The supercritical fluid used in the method for producing a ceramic body according to a preferred embodiment of the present invention has high dissolving power like a liquid, and the monomer can be thus dissolved in the supercritical fluid. In addition, the supercritical fluid has a high diffusion coefficient like a gas, and has excellent permeability, and the supercritical fluid with the monomer dissolved therein can be thus allowed to enter even into nano-level fine voids.

Thus, in the step of allowing the supercritical fluid containing the monomer to enter into the void between the conductor and the ceramic body, the supercritical fluid with the monomer dissolved therein can be allowed to enter even into nano-level fine voids present between the conductor and the ceramic body. Furthermore, the polymerization of the monomer can fill even the nano-level fine voids present between the conductor and the ceramic body with the polymer in the step of filling the void between the conductor and the ceramic body with the polymer.

Therefore, it is possible to more effectively prevent the ingress of moisture into the void between the conductor and the ceramic body in the ceramic body including therein the conductor.

In the method for producing a ceramic body according to a preferred embodiment of the present invention, the supercritical fluid is preferably carbon dioxide in a supercritical state.

Carbon dioxide has a critical temperature of 31.1° C. and a critical pressure of 7.38 Mpa, and reaches a supercritical state at not less than the critical temperature and not less than the critical pressure. For this reason, carbon dioxide can be brought into a supercritical state under relatively mild conditions. In addition, carbon dioxide in a supercritical state is easily accessible, because the carbon dioxide is not toxic, is chemically inactive, and thus is inexpensive but has a high purity. Furthermore, the carbon dioxide in a supercritical state becomes carbon dioxide contained in the atmosphere at ordinary temperatures and pressures. For this reason, the carbon dioxide in a supercritical state, which is allowed to enter into the void between the conductor and the ceramic body, can be easily removed by releasing the carbon dioxide into the atmosphere at ordinary temperatures and pressures.

In addition, in the method for producing a ceramic body according to a preferred embodiment of the present invention, the ceramic body is preferably a ceramic laminated body including a plurality of stacked ceramic layers, and a plurality of conductor layers interposed between the plurality of ceramic layers.

In this case, the production method according to a preferred embodiment of the present invention can be applied to a method for producing a ceramic electronic component including the ceramic laminated body. For example, the application of the production method according to a preferred embodiment of the present invention makes it possible to more effectively prevent the ingress of moisture into the void between the conductor and the ceramic body in an electronic component including the ceramic laminated body, by filling even nano-level fine voids present between the conductor and the ceramic body with the polymer before forming external electrode layers. Therefore, inhibiting substances resistant to plating deposition will not remain on the surfaces of the external electrode layers. Thus, in the case of forming plating layers in a subsequent step, no defective plating deposition will be caused on the surfaces of the external terminal electrodes, or in the case of mounting the chip-type electrode component onto a substrate or the like by soldering, no defects will be caused.

Furthermore, when the interfaces between the conductor layers and the ceramic layers are exposed at an external surface of the ceramic laminated body, the application of the production method according to a preferred embodiment of the present invention makes it possible to more effectively prevent the ingress of moisture into the void between the conductor and the ceramic body.

In addition, in the method for producing a ceramic body according to a preferred embodiment of the present invention, the polymer obtained by the polymerization of the monomer is preferably polyimide.

As described above, various preferred embodiments of the present invention make it possible to more effectively prevent the ingress of moisture into the void between the conductor and the ceramic body in the ceramic body including therein the conductor. Thus, for example, the application of a preferred embodiment of the present invention to a method for producing a laminated ceramic electronic component such as a chip-type laminated ceramic capacitor can prevent the insulation resistance from being decreased, and improve the reliability of the laminated ceramic electronic component.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic cross-sectional view illustrating a first production step for a laminated ceramic capacitor as an example of a ceramic body according to a preferred embodiment of the present invention.

FIG. 2 is a schematic cross-sectional view illustrating a second production step for a laminated ceramic capacitor as an example of a ceramic body according to a preferred embodiment of the present invention.

### DETAILED DESCRIPTION OF THE PREFERRED EMBODIMENTS

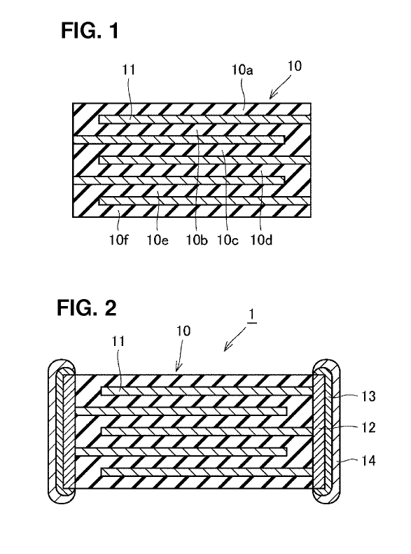

First, a laminated ceramic capacitor will be described as an example of a ceramic body according to a preferred embodiment of the present invention. FIGS. 1 and 2 are cross-sectional views illustrating production steps for a general laminated ceramic capacitor.

First, slurry is prepared which contains a ceramic raw material powder. This slurry is formed into a sheet to prepare ceramic green sheets. Onto the surfaces of the ceramic green sheets, a conductive paste as a raw material for internal electrode layers is applied in accordance with a predetermined pattern. This conductive paste is preferably composed of a metal powder, a solvent, and varnish, for example.

Next, the multiple ceramic green sheets with the conductive paste applied are stacked, and subjected to thermocompression bonding to prepare an integrated raw laminated body. As shown in FIG. 1, this raw laminated body is subjected to firing to prepare a ceramic laminated body 10 as a ceramic body. This ceramic laminated body 10 includes a plurality of internal electrode layers 11 located therein as internal conductors. The internal electrode layers 11 include some end surfaces exposed at the external surface of the ceramic laminated body 10.

Next, as shown in FIG. 2, a conductive resin is attached onto the outer surface of the ceramic laminated body 10 at which some end surfaces of the internal electrode layers 11 are exposed. Thus, external electrode layers 12 are arranged on the outer surface of the ceramic laminated body 10 so as to be electrically connected to the specific internal electrode layers 11.

Finally, in order to enhance soldering performance, first and second plating layers 13, 14 preferably are formed on the surfaces of the external electrode layers 12, if necessary.

The laminated ceramic capacitor 1 thus produced includes the cuboid-shaped ceramic laminated body 10 containing, for example, a BaTiO₃ based compound. The ceramic laminated body 10 includes a plurality of (six in the figure by way of example) stacked ceramic layers 10a, 10b, 10c, 10d, 10e, 10f and a plurality of (five in the figure by way of example) internal electrode layers 11 arranged along the interfaces between the plurality of ceramic layers 10a, 10b, 10c, 10d, 10e, 10f. The internal electrode layers 11 are arranged so as to reach the outer surface of the ceramic laminated body 10. The internal electrode layers 11 extracted to one end surface of the ceramic laminated body 10 and the internal electrode layers 11 extracted to the other end surface thereof are arranged alternately in the ceramic laminated body 10 so that electrostatic capacitance can be generated with the dielectric ceramic layers therebetween. It is to be noted that the conductive material of the internal electrode layer 11 is preferably nickel or a nickel alloy, for example, in view of the reduction in cost.

In order to achieve the electrostatic capacitance, the external electrode layers 12 are arranged on the end surfaces of the outer surface of the ceramic laminated body 10 so as to be electrically connected to any specific ones of the internal electrode layers 11. As a conductive material contained in the external electrode layers 12, the same conductive material can be used as in the case of the internal electrode layers 11, and further, silver, palladium, a silver-palladium alloy, etc. can also be used. The external electrode layers 12 are preferably formed from a conductive resin, for example. It is to be noted that while an example of electrode layers composed of a conductive resin has been given as the external electrode layers 12 in the above description, the external electrode layers 12 are not limited to the electrode layers composed of a conductive resin, and may be thin film external electrodes formed by sputtering, electrodes formed by plating, or electrodes obtained by other methods.

In addition, if necessary, first plating layers 13 composed of nickel, copper, or the like preferably are formed on the external electrode layers 12, and second plating layers 14 composed of solder, tin, or the like are further formed thereon.

A method for producing a ceramic body according to a preferred embodiment of the present invention is applied between the production steps for a laminated ceramic capacitor, which are shown in FIGS. 1 and 2.

First, in the method for producing a ceramic body according to a preferred embodiment of the present invention, a supercritical fluid containing a monomer, for example, carbon dioxide in a supercritical state is allowed to enter into voids between the internal electrode layers 11 as conductors and the ceramic laminated body 10 as a ceramic body as shown in FIG. 1. Specifically, the above production step is carried out in a predetermined heat-resistant pressure-resistant container or the like which is able to hold the supercritical fluid.

Next, the voids between the internal electrode layers 11 and the ceramic laminated body 10 are filled, preferably completely, with the polymer by the polymerization of the monomer.

The supercritical fluid used as described above has high dissolving power like a liquid, and the monomer can be thus dissolved in the supercritical fluid. In addition, the supercritical fluid has a high diffusion coefficient like a gas, and has excellent permeability, and the supercritical fluid with the monomer dissolved therein can be thus allowed to enter even into nano-level fine voids.

Thus, in the step of allowing the supercritical fluid containing the monomer to enter into the voids between the internal electrode layers 11 and the ceramic laminated body 10, the supercritical fluid with the monomer dissolved therein can be allowed to enter even into nano-level fine voids present between the internal electrode layers 11 and the ceramic laminated body 10. Furthermore, the polymerization of the monomer can fill even the nano-level fine voids present between the internal electrode layers 11 and the ceramic laminated body 10 with the polymer in the step of filling the voids between the internal electrode layers 11 and the ceramic laminated body 10 with the polymer. In this case, while the supercritical fluid with the monomer dissolved therein can enter into the fine voids, the polymer produced by the polymerization of the monomer will not be dissolved in the supercritical fluid, thereby blocking the voids. It is to be noted that the supercritical fluid may be removed after the polymerization of the monomer.

Therefore, in the laminated ceramic capacitor 1 as an example of the ceramic body including therein conductors, it is possible to more effectively prevent the ingress of moisture into the voids between the internal electrode layers 11 and the ceramic laminated body 10.

In the method for producing a ceramic body according to a preferred embodiment of the present invention, various types of polymerization methods can be applied depending on the monomer used. In place of the monomer, monomer precursors may be used, for example.

The supercritical fluid containing the monomer may be allowed to enter into the voids after introducing a polymerization initiator or a catalyst in advance into the voids by allowing a supercritical fluid with the polymerization initiator or catalyst dissolved therein to enter into the voids. In order to increase the solubility in the supercritical fluid with the monomer, auxiliary solvents may be used.

Further, examples of the ceramic body including therein conductors are not limited to laminated ceramic capacitors, but include laminated chip inductors, laminated piezoelectric elements, multilayer ceramic substrates, and laminated chip thermistors.

As described above, in the method for producing a ceramic body according to a preferred embodiment of the present invention, the supercritical fluid is preferably carbon dioxide in a supercritical state, for example.

Carbon dioxide has a critical temperature of 31.1° C. and a critical pressure of 7.38 Mpa, and reaches a supercritical state at not less than the critical temperature and not less than the critical pressure. For this reason, carbon dioxide can be brought into a supercritical state under relatively mild conditions. In addition, carbon dioxide in a supercritical state is easily accessible, because the carbon dioxide is not toxic, chemically inactive, and thus available inexpensively with a high purity. Furthermore, the carbon dioxide in a supercritical state becomes carbon dioxide contained in the atmosphere at ordinary temperatures and pressures. For this reason, the carbon dioxide in a supercritical state, which is allowed to enter into the voids between the internal electrode layers 11 and the ceramic laminated body 10, can be easily removed by releasing the carbon dioxide into the atmosphere at ordinary temperatures and pressures.

In addition, in the method for producing a ceramic body according to a preferred embodiment of the present invention, the ceramic body is preferably the ceramic laminated body 10 including the plurality of stacked ceramic layers 10a, 10b, 10c, 10d, 10e, 10f, and the plurality of internal electrode layers 11 defining conductor layers interposed between the plurality of ceramic layers 10a, 10b, 10c, 10d, 10e, 10f as described above.

In this case, the production method according to a preferred embodiment of the present invention can be applied to the method for producing a ceramic electronic component including the ceramic laminated body 10, as an example, the laminated ceramic capacitor 1. For example, the application of the production method according to a preferred embodiment of the present invention makes it possible to more effectively prevent the ingress of moisture into the voids between the internal electrode layers 11 and the ceramic laminated body 10 in the laminated ceramic capacitor 1 as an electronic component including the ceramic laminated body 10, by filling even nano-level fine voids present between the internal electrode layers 11 and the ceramic laminated body 10 with the polymer before forming the external electrode layers 12. Therefore, inhibiting substances against plating deposition will not remain on the surfaces of the external electrode layers 12. Thus, in the case of forming the first and second plating layers 13, 14 as plating layers in a subsequent step, no defective plating deposition will be caused on the surfaces of the external terminal electrodes, or in the case of mounting the chip-type electrode component onto a substrate or the like by soldering, no defects will be caused.

Furthermore, when the interfaces are exposed between the internal electrode layers 11 as conductor layers and the ceramic layers 10a, 10b, 10c, 10d, 10e, 10f in the ceramic laminated body 10 as shown in FIG. 1, the application of the production method according to a preferred embodiment of the present invention makes it possible to more effectively prevent the ingress of moisture into the voids between the internal electrode layers 11 and the ceramic laminated body 10.

In addition, in the method for producing a ceramic body according to a preferred embodiment of the present invention, the polymer obtained by the polymerization of the monomer is favorably excellent in heat resistance, insulation reliability under high-temperature and high-humidity environments, etc, and preferably polyimide.

### Example

A non-limiting example of a preferred embodiment of the present invention will now be described. First, 10 mmol/L dimethylformamide (DMF) solutions of pyromellitic dianhydride (PMDA) and diaminodiphenyl ether (ODA) were respectively prepared as monomer precursors.

The fired ceramic laminated body 10 (dimensions: 1.0 mm×0.5 mm×0.5 mm) for the laminated ceramic capacitor 1, with the internal electrode layers 11 composed of nickel and exposed alternately to the both end surfaces as shown in FIG. 1, was prepared for 100 pieces. These ceramic laminated bodies 10 were put into a heat-resistant pressure-resistant container with an internal volume of 50 ml, and the container was hermetically sealed. Then, a carbon dioxide gas was introduced into the heat-resistant pressure-resistant container, the temperature and pressure in the heat-resistant pressure-resistant container were increased to bring the carbon dioxide into a supercritical state, and the temperature in heat-resistant pressure-resistant container was kept at 120° C. and the pressure therein was kept at 20 MPa.

Next, while keeping the temperature and pressure in the heat-resistant pressure-resistant container respectively at 120° C. and 20 MPa, the DMF solution of PMDA and the DMF solution of ODA were each introduced at a flow rate of 0.5 mL/min into the heat-resistant pressure-resistant container, along with carbon dioxide at a flow rate adjusted to 5 g/min.

After a lapse of 120 minutes, the introduction of the DMF solution of PMDA and the DMF solution of ODA into the heat-resistant pressure-resistant container was stopped while introducing only the carbon dioxide into the heat-resistant pressure-resistant container. In this process, polymerization is considered to be induced.

After a further lapse of 30 minutes, the introduction of the carbon dioxide into the heat-resistant pressure-resistant container was stopped. Then, by returning the temperature and pressure in the heat-resistant pressure-resistant container to ordinary temperatures and pressures, vaporized carbon dioxide was discharged to the outside of the heat-resistant pressure-resistant container and removed. The ceramic laminated bodies 10 were taken out of the heat-resistant pressure-resistant container with the carbon dioxide removed therefrom.

In this way, the PMDA and ODA dissolved in the carbon dioxide in a supercritical state are considered to spread into voids between the internal electrode layers 11 and the ceramic body 10, that is, fine voids present at the interfaces between the internal electrode layers 11 and the ceramic layers 10a, 10b, 10c, 10d, 10e, 10f, as fine defects in the ceramic body, and polymerized in the defects to produce a polyamide acid (PAA). Furthermore, the polyamide acid (PAA) is considered to be changed to a polyimide (PI) by imidization.

Next, after removing the product (polyimide) adhering to a necessary portion of the surface of the ceramic laminated body 10, a conductive resin as a raw material for the external electrode layers 12 was attached onto the outer surface of the ceramic laminated body 10 with some end surfaces of the internal electrode layers 11 exposed, as shown in FIG. 2. Thus, the external electrode layers 12 were formed on the outer surface of the ceramic laminated body 10 so as to be electrically connected to the specific internal electrode layers 11.

Finally, in order to enhance soldering performance, a nickel (Ni) plating layer as a first plating layer 13 and a tin (Sn) plating layer as a second plating layer 14 were formed sequentially on the surfaces of the external electrode layers 12 by an electrolytic plating method. In this way, the laminated ceramic capacitor 1 was prepared.

The observation of a cross section of the laminated ceramic capacitor 1 obtained confirmed that the voids between the internal electrode layers 11 and the ceramic body 10, that is, the fine voids present at the interfaces between the internal electrode layers 11 and the ceramic layers 10a, 10b, 10c, 10d, 10e, 10f, as fine defects in the ceramic body were filled with the polyimide as a polymer.

As a result, the fine defects of the ceramic body are blocked by the polyimide, thereby making it possible to prevent the ingress of moisture. Thus, the lifetime characteristic is improved in a load test on the moisture resistance of the laminated ceramic capacitor 1, and more specifically, the reliability of the laminated ceramic capacitor 1 is improved.

The preferred embodiments and examples disclosed herein are all to be considered by way of example in all respects, and are not limiting in any respect. The scope of the present invention is defined by the appended claims, not by the above preferred embodiments and examples, and intended to encompass all modifications and variations within the spirit and scope equivalent to the claims.

For example, the application of a preferred embodiment of the present invention to a method for producing a laminated ceramic electronic component such as a chip-type laminated ceramic capacitor can prevent the insulation resistance from being decreased, and improve the reliability of the laminated ceramic electronic component.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A ceramic component comprising:
a ceramic body;
an conductor located in the ceramic body;
a void located between the conductor and the ceramic body; and
a polymer located in the void between the conductor and the ceramic body.

2. The ceramic component according to claim 1, wherein the ceramic body is a multilayered laminated ceramic body including a plurality of stacked ceramic layers and conductor layers interposed between the plurality of ceramic layers.

3. The ceramic component according to claim 1, wherein the ceramic component is one of a capacitor, an inductor, a piezoelectric element, a multilayer ceramic substrate, and a thermistor.

4. The ceramic component according to claim 1, wherein the conductor includes an end surface exposed at an external surface of the ceramic body.

5. The ceramic component according to claim 4, further comprising an external electrode located on the ceramic body so as to be electrically connected to the conductor.

6. The ceramic component according to claim 5, further comprising first and second plating layers located on the external electrode.

7. The ceramic component according to claim 1, wherein the void is completely filled with the polymer.

8. The ceramic component according to claim 1, wherein the void is a nano-level void.

9. The ceramic component according to claim 1, wherein the polymer is made of a polymerized monomer.

10. The ceramic component according to claim 1, wherein the polymer is made of a polyimide.

11. The ceramic component according to claim 1, further comprising a plurality of conductors and a plurality of voids between the ceramic body and the plurality of conductors, wherein the polymer is located in each of the plurality of voids.

12. The ceramic component according to claim 10, wherein each of the plurality of voids is completely filled with the polymer.

13. A method for producing a ceramic body including therein a conductor, the method comprising the steps of:
applying a supercritical fluid containing a monomer such that the supercritical fluid containing the monomer enters into a void between the conductor and the ceramic body; and
applying a polymer formed by polymerization of the monomer into the void between the conductor and the ceramic body.

14. The method for producing a ceramic body according to claim 13, wherein the step of applying a polymer includes completely filling the void with the polymer.

15. The method for producing a ceramic body according to claim 13, wherein the supercritical fluid is carbon dioxide in a supercritical fluid.

16. The method for producing a ceramic body according to claim 13, wherein the ceramic body is a ceramic laminated body including a plurality of stacked ceramic layers and conductor layers interposed between the plurality of ceramic layers.

17. The method for producing a ceramic body according to claim 16, wherein interfaces between the conductor layers and the ceramic layers are exposed at an external surface of the ceramic laminated body.

18. The method for producing a ceramic body according to claim 13, wherein the polymer formed by the polymerization of the monomer is a polyimide.

19. The method for producing a ceramic body according to claim 13, wherein the void is a nano-level void.

20. The method for producing a ceramic body according to claim 13, further comprising the step of introducing a polymerization initiator or a catalyst into the void before the step of applying a supercritical fluid containing a monomer.
